(19) United States
(12) Patent Application Publication
(10) Pub. No.: US 2014/0335651 A1
(43) Pub. Date: Nov. 13, 2014

(54) INKS AND PASTES FOR SOLAR CELL FABRICATION

(71) Applicant: Sichuan Yinhe Chemical Co., Ltd., Sichuan (CN)

(72) Inventors: Yunjun LI, Austin, TX (US); Peter B. LAXTON, Austin, TX (US); James P. NOVAK, Austin, TX (US); David Max ROUNDHILL, Seattle, WA (US)

(21) Appl. No.: 14/341,182

(22) Filed: Jul. 25, 2014

Related U.S. Application Data
(63) Continuation-in-part of application No. 13/128,577, filed on May 10, 2011.
(60) Provisional application No. 61/114,860, filed on Nov. 14, 2008.

(51) Int. Cl. H01L 31/02; H01L 31/0224

(52) U.S. Cl. CPC H01L 31/02008; H01L 31/022441
USPC 438/98

(57) ABSTRACT

A silicon solar cell is formed with an N-type silicon layer on a P-type silicon semiconductor substrate. An aluminum ink composition is printed on the back of the silicon wafer to form back contact electrodes. The back contact electrodes are sintered to produce an ohmic contact between the electrodes and the silicon layers. The aluminum ink composition may include aluminum powders, a vehicle, an inorganic polymer, and a dispersant. Other electrodes on the solar cell can be produced in a similar manner with the aluminum ink composition.

### CROSS-REFERENCE TO RELATED APPLICATIONS

This application claims priority to U.S. patent application Ser. No. 13/128,577, which claims priority to International Application Number PCT/US2009/064162, which claims priority to U.S. Provisional Patent Application Ser. No. 61/114,860.

### TECHNICAL FIELD

This application relates in general to solar cells, and in particular, to formation of electrodes pertaining to solar cells.

### BACKGROUND

Contacts are a critical part of photovoltaic (PV”) technology. In particular, they pose difficulties in both silicon and copper indium gallium selenide (“CIGS”) technologies. The cell performance of the CIGS devices fabricated using transparent conducting oxide (“TCO”) back contacts deteriorates at high absorber deposition temperatures used for conventional CIGS devices with molybdenum (Mo) back contacts. The deterioration in cell performance is due to reduction in the fill factor originating from the increased resistivity of the TCOs. Increased resistivity is mainly attributable to the removal of fluorine (F) from tin oxide (SnO₂):F and the undesirable formation of a gallium oxide (Ga₂O₃) thin layer at the CIGS/ITO and CIGS/zinc oxide (ZnO):aluminum (Al) interfaces. The formation of Ga₂O₃ has been eliminated by inserting a thin Mo layer between the indium tin oxide (“ITO”) and CIGS layers. An improved metal interconnect system for shallow planar doped silicon substrate regions has been developed using Al and Al alloys as contacts and interconnects. Contacts and interconnects have been provided using Al for Schottky contacts and silicon (Si) doped Al for ohmic contacts. This approach takes advantage of the adherent property of Al to Si and the Schottky barrier relationship while minimizing the Al to Si alloying or pitting by the use of Al and Si doped Al metal contact and interconnect system. Devices assembled using these Mo and Al contacts are illustrated in FIG. 1.

The current direction of silicon solar cell technology development is to use thinner silicon wafers and improve conversion efficiency. The reduction in wafer thickness reduces overall material usage and cost because the costs of materials account for almost 50% of the total cost of silicon solar cells. These thin silicon wafers are often very brittle, and typical methods for application of conductive feed lines, such as screen-printing, are detrimental. Non-contact printing would lead to less breakage of thinner silicon wafers and increase manufacturing yield. Aluminum inks that can be applied to a silicon solar cell for back contacts using non-contact printing techniques would be advantageous for the silicon solar industry. Available glass frit containing Al pastes are meant for contact-type printing.

### BRIEF DESCRIPTION OF THE DRAWINGS

FIG. 1 illustrates examples of current configurations of a CIGS and a silicon solar cell.

FIG. 2 illustrates a chemical structure of a PPSQ ladder-like inorganic polymer (HO-PPSQ-H).

FIG. 3 illustrates a digital image showing that after sintering, approximately a 7 μm thick BSF layer is formed on aluminum coated silicon.

FIG. 4 illustrates a rear junction design with interdigitated back contacts.

FIG. 5 is a digital image of aluminum ink/paste printed on a silicon wafer using an aerosol jet printer achieving less than 60 μm wide lines.

FIG. 6 illustrates a table of adhesion properties for aluminum inks.

FIG. 7 illustrates a table of sheet resistance properties for aluminum inks.

FIG. 8 illustrates a table of photosintering properties for aluminum inks.

FIG. 9 illustrates an aerosol application process.

FIG. 10 illustrates a screen printing application process.

FIG. 11 illustrates an inkjet application process.

FIG. 12 shows a table of properties of inkjet printable aluminum ink.

FIG. 13 illustrates a cross-section view of a structure of a solar cell device.

FIG. 14 illustrates a cross-section view of embodiments of the present invention.

### DETAILED DESCRIPTION

There is an increasing need to develop improved processes for contacts different from the current physical vapor deposition (“PVD”) and photolithography based approaches that are presently used. In particular, it would be desirable to develop solution based atmospheric processes to generate these contacts. This approach would be much more cost effective, environmentally benign, and more materials efficient. This approach is proving very successful for silver and for nickel/copper top contacts. To date, however, it has been very difficult to make good precursors from both Al and Mo because of their inherent chemistries. Al is problematic because it is very reactive both in the metallic and in a metal organic form, and Mo because it is prone to oxidation and also because it is more difficult to synthesize precursors. One approach to both of these metallizations is to use nanoparticle based inks. Recently significant progress has been made on the practical synthesis of large amounts of monodispersed small particles of both of these metals. In addition, considerable work has been done on the capping of these nanoparticles with chemical bonding agents, which stabilize the particle surface prior to the final dielectrode to a metal contact where they are released cleanly. Non-contact printing would lead to less breakage of thinner silicon wafers and increase manufacturing yield. Aluminum inks/pastes that can be applied to a silicon solar cell for back contacts using non-contact printing techniques would be advantageous for the silicon solar industry.

Aluminum inks or pastes (herein, the formulations may be implemented in a relatively low viscosity ink, or a higher viscosity paste) are used for industrial-scale silicon solar cell manufacturing to form an alloyed Back Surface Field (“BSF”) layer to improve the electrical performance of silicon solar cells. The most important variables that control the cell performance under industrial processing conditions are the a) ink/paste chemistry, b) deposition weight and c) firing conditions. There is a need to reduce the silicon wafer thickness to improve the silicon utilization and to reduce the solar cell materials cost. A wafer bow resulting from the addition of an Al layer becomes an issue when the silicon wafer thickness is decreased below 240 microns. Generally, the bow tends to decrease with a reduction in the ink/paste deposit amount, but there is a practical lower limit below which screen-printed Al ink/paste will result in a non-uniform BSF layer. Recently more attention has been given to understanding the effects of ink/paste chemistry and firing conditions on microstructure development (see, S. Kim et al., “Aluminum Pastes For Thin Wafers,” Proceedings, IEEE PVSC, Orlando (2004); F. Huster, “Investigation of the Alloying Process of Screen Printing Aluminum Pastes for the BSF Formation on Silicon Solar Cells,” 20th European Photovoltaic Solar Energy Conference, Barcelona (2005)).

Al inks/pastes may be formulated with Al powders, a leaded glass frit, vehicles, and additives mixed with an organic vehicle. However, European Union regulation may in the future require the elimination of lead from the final assembled solar cell.

Some objectives in manufacturing new generation Al inks/pastes are:

1) Eliminate lead-containing glass frit from Al inks/pastes;

2) Reduce the amount of ink/paste deposited in order to decrease the silicon wafer bow when the thickness of the silicon wafer is decreased below 240 microns;

3) A BSF layer formed to achieve better electrical performance of the cells;

4) Decrease the coefficient of thermal expansion (“CTE”) mismatch between the fired Al ink/paste and silicon.

Infrared (“IR”) belt furnaces, which are similar to a RTP (Rapid Thermal Process), may be used for sintering Al ink/paste for the back contacts of a silicon solar cell. The process time is a few minutes for firing Al inks/pastes. At high firing temperatures of up to 800° C., an Al alloy with silicon is formed during the process. The Al ink/paste is fired in a nitrogen environment.

Aluminum inks/pastes may be formulated with combinations of alcohols, amines, mineral acids, carboxylic acids, water, ethers, polyols, siloxanes, polymeric dispersants, BYK dispersants and additives, phosphoric acid, dicarboxylic acids, water-based conductive polymers, polyethylene glycol derivatives such as the Triton family of compounds, esters and ether-ester combinations. Both nanosized (e.g., nanoparticles or nanopowders, which are used interchangeably herein) and micro-sized Al particles may be used in the formulations.

Aluminum ink/paste formulation without using a traditional glass frit binder

A glass frit powder may be used as an inorganic binder to make functional materials adhere to the substrate when the firing process fuses the frit materials and bonds them to the substrate. A glass frit matrix is basically comprised of a metal oxide powder, such as PbO, SiO₂, or B₂O₃. Due to the nature of the powder form of these oxides, the discontinuous coverage of the frit material on the substrate creates a fired Al adhesion-uniformity problem. To improve the adhesion of Al on silicon, a material having both a relatively strong bond strength to both Al and the substrate needs to be introduced into the formulation of the Al inks/pastes, which is addressed by embodiments of the present invention.

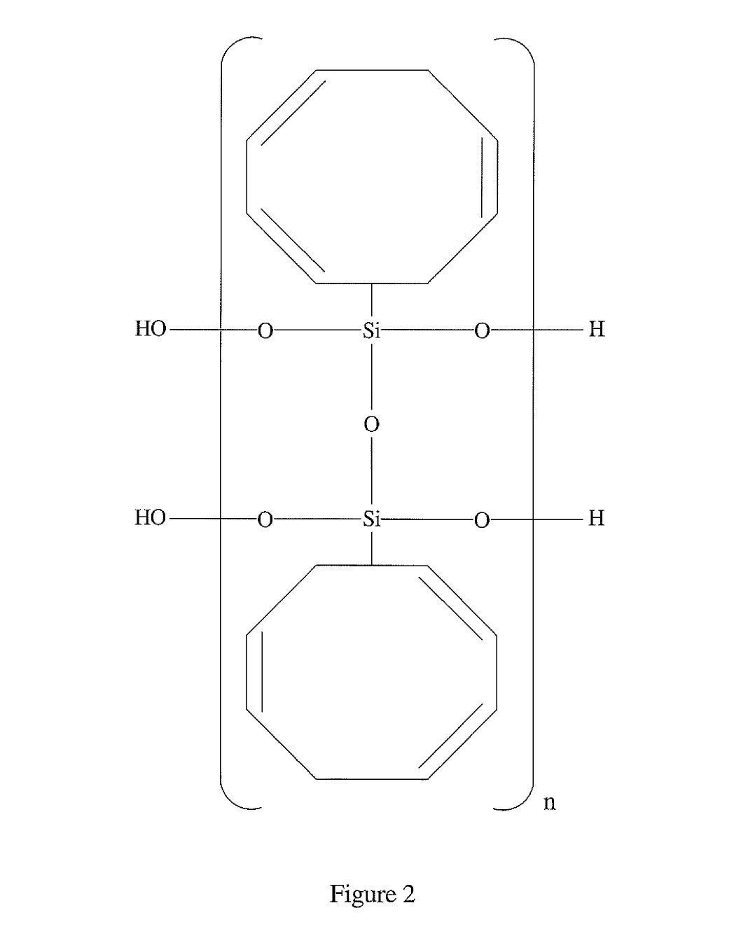

A silicon ladder-like polymer, polyphenylsilsesquioxane (“PPSQ”), is an inorganic polymer that has a cis-syndiotactic double chain structure, as illustrated in FIG. 2 (see, J. F. Brown, Jr., J. Polym. Sci. 1C (1963) 83). This material possesses the good physical properties of SiO₂ because of functional groups. An example of PPSQ is polyphenylsilsesquioxane ((C₆H₅SiO_{1.5})ₓ). The PPSQ polymer may be spin-on coated and/or screen printed as a thin or thick film onto substrates as a dielectric material having good adhesion for microelectronics applications. Unlike glass frit powder, this PPSQ material can be dissolved in a solvent to make a solution so that powders can be dispersed in the adhesive binder matrix to obtain a uniform adhesion layer on the substrate. This material can be cured (e.g., at 200° C.) and has a thermal stability at higher temperatures (e.g., 500° C.), making it a good binder for ink/paste formulations to replace the glass frit material. These PPSQ-type polymers can be bond-terminated by other functional chemical groups such as C₂H₅O-PPSQ-C₂H₅ and CH₃-PPSQ-CH₃. This inorganic polymer, as a novel alternative to glass flit, provides for inks/pastes to be formulated such that they can be printed by a non-contact method. This produces thinner, more brittle, lower cost silicon wafers that would otherwise be destroyed by the printing methods required for glass frit containing inks/pastes.

Upon drying and sintering of Al inks/pastes with such an inorganic polymer, the vehicle and dispersant are decomposed and evaporated. The inorganic polymer is also decomposed, but leaves behind a silica structure, which replaces the function of the current state of the art glass frit. PV cell electrodes made in this way are then primarily composed of Al with some SiO₂.

An advantage of using a PPSQ binder in Al inks/pastes is that the silicon residue in the fired (e.g., sintered) Al decreases the thermal expansion mismatch between the silicon and the fired Al. The result is that any wafer bow is significantly reduced with PPSQ-based Al inks/pastes.

A PPSQ solution may be prepared by mixing ˜40-50 wt. % of the PPSQ material and ˜40-50 wt. % 2-butoxyethyl acetate with stirring (e.g, for 30 minutes). The viscosity of PPSQ solutions may range from ˜500-5000 cP. Utilizing this PPSQ solution, PPSQ Al inks/pastes may be formulated as follows:

### Formulation 1

A) An Al ink/paste (P-Al-3-PQ-1) may be formulated with Al powders (e.g., 7 g of 3 micron Al micro-powders), ethyl cellulose (e.g., 1 g), terpineol (e.g., 4 g), and the PPSQ solution (e.g., 1 g). The ink/paste may be mixed in a glass beaker and passed 10 times through a three-roll mill machine.

B) An Al ink/paste (P-Al-3-Al-100-PQ-1) may be formulated with Al powders (e.g., 6 g of 3 micron Al micro-powders and 1 g of 100 nm Al nanopowders), ethyl cellulose (e.g., 1 g), terpineol (e.g., 4 g), and the PPSQ solution (e.g., 1 g). The ink/paste may be mixed in a glass beaker and passed 10 times through a three-roll mill machine.

### Formulation 2

An Al ink/paste (P-Al-3-Al-100-PQ-1) may be formulated with Al powders (e.g., 6 g of 3 micron Al micro-powders and 1 g of 100 nm Al nanopowders), ethyl cellulose (e.g., 1 g), terpineol (e.g., 4 g), and the PPSQ solution (e.g., 1 g). The ink/paste may be mixed in a glass beaker and passed 10 times through a three-roll mill machine.

### Thermal Sintering Aluminum Inks/Pastes

The Al ink/paste of P-AL-3-G-1 may be coated on silicon and aluminum by draw-bar deposition. The coating may be dried at 100° C. for 10 minutes and then put in a vacuum tube furnace for thermal sintering. The sintering may be done in a nitrogen environment. The sintering temperature may be ˜750° C. The furnace may require 1 hour to heat up to 750° C. from room temperature and to then cool back down to room temperature.

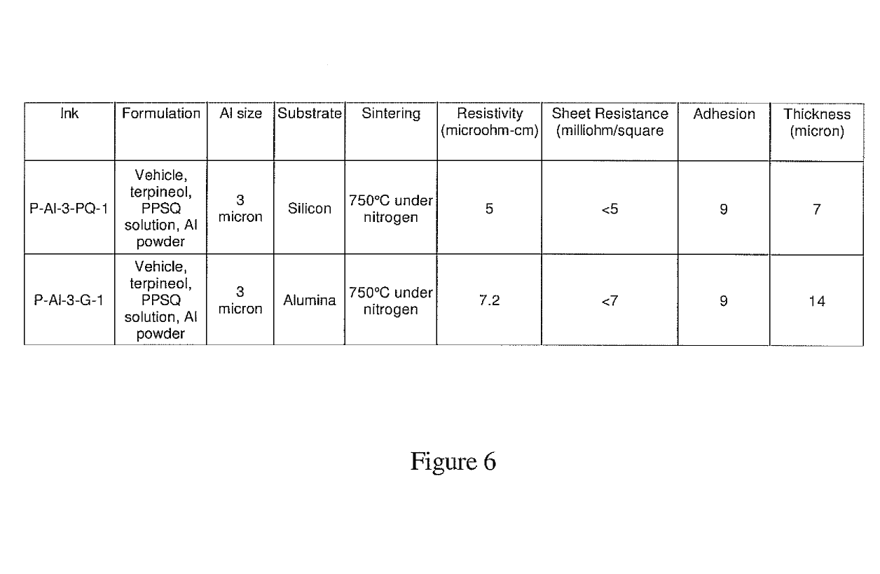

A sheet resistance down to 3 milliohms/square on silicon and ceramic is achieved. No Al beads are observed after sintering. The Al coating has a relatively smooth surface without any large Al beads being present on the surface. The adhesion may be evaluated by a tape test. For the adhesion score of 9 in the table shown in FIG. 6, no materials are observed adhering onto the tape after it is peeled off.

### Rapid Thermal Sintering Aluminum Ink/Paste in Air and Vacuum

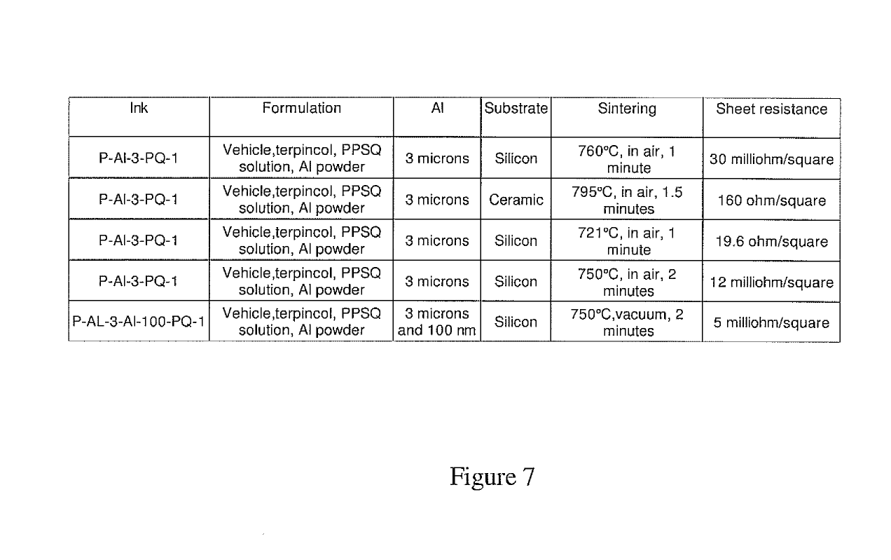

The Al ink/paste P-AL-3-G-1 may be coated onto silicon and aluminum by draw-bar deposition. The coating may be dried at 100° C. for 10 minutes. Alternatively, the coatings may be dried at a temperature between 200° C. and 250° C. in air for approximately I minute. The tube furnace may be then heated to 760° C. in air. The dried Al samples on a quartz substrate holder may be slowly pushed into the tube furnace in air. The samples may be kept at 760° C. for one minute and then slowly pulled out of the tube furnace. A sheet resistance of 30 milliohms/square can be achieved on silicon, as shown in the table of FIG. 7.

Lower resistances may be achieved when the Al ink/paste samples are sintered at 750° C. in vacuum. The dried Al samples on a quartz substrate holder may be slowly pushed into the 750° C. tube furnace in air. A mechanical pump may be then used to pump down the tube furnace for about one minute. After pumping for 1 minute, the pump may be turned off and the tube furnace vented to the atmosphere. It may require approximately one minute to vent the furnace. After venting, the sample is pulled out of the furnace and allowed to cool down to room temperature. A resistance of 5 milliohms/square can be obtained with vacuum sintering in about two minutes.

### Microwave Sintering Aluminum Ink/Paste in Air

The Al ink/paste may be deposited on either a silicon or ceramic substrate. A microwave oven (standard commercial appliance) may be used to process the Al inks/pastes. The processing time may be from 1 to 5 minutes.

The microwave processing is successful on Al ink/paste coated onto a silicon substrate, but no sintering was observed for Al on a ceramic substrate. The reason is that the thermally conductive silicon can absorb microwave energy to become heated itself This heat from the silicon facilitates the sintering of the coated Al ink/paste. A sheet resistance of 5 milliohm/square on the corners of samples can be achieved with microwave sintering.

An advantage of the microwave process is that sintering may be carried out in air using the relatively short time of less than 10 minutes. Conductive substrates such as silicon may be required. This may create a non-uniformity problem because of the non-uniform heating on the Al ink/paste. For silicon based solar cells, this microwave energy may also destroy the p-n junction, or damage the substrate or electrodes.

### Sintering of Aluminum Ink/Paste with Rapid Thermal Process (“RTP”)

Traditional IR-belt furnaces or rapid thermal processes may also be used for sintering Al ink/paste for fabricating electrical contacts on silicon. The process time may be a few minutes for firing Al inks/pastes. At high temperatures up to 800° C., an Al alloy with silicon is formed during the process. It may be necessary to fire the Al ink/paste in a nitrogen environment to achieve a lower resistance. A sheet resistance of 5 milliohms/square on the corners of samples can be achieved with the RTP sintering or IR-belt furnaces.

### Photosintering

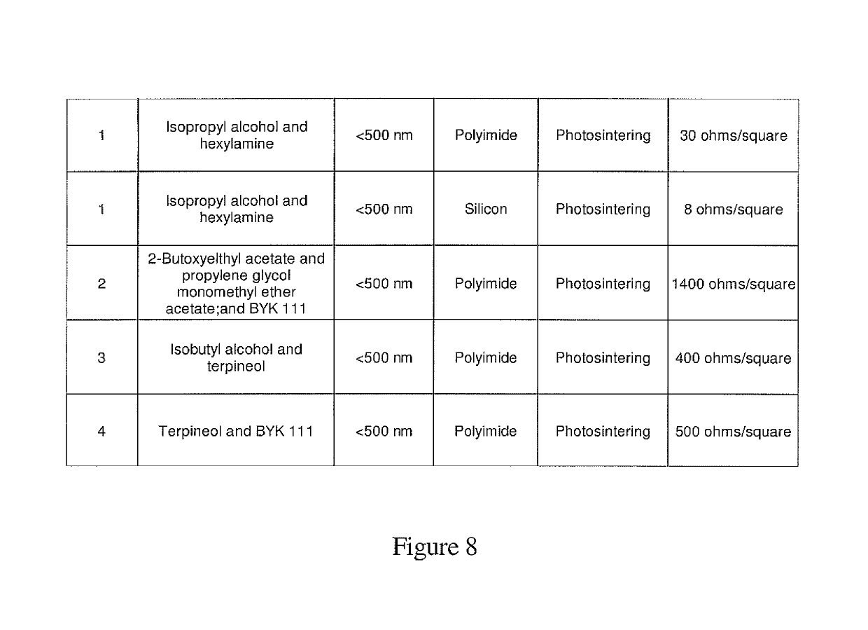

Aluminum inks/pastes are prepared and cured by photosintering. Photosintering involves curing the printed metallic ink/paste with a short high intensity pulse of light that converts the metal nanoparticles into a metallic conductor. Examples of results are shown in FIG. 8. This method has been previously used for nanoparticles of silver, copper, and other metals, but not for Al or Mo. These metals are particularly challenging because Al forms a strongly coherent oxide layer and Mo has a very high melting point that causes sintering to a conductor to be difficult.

### Summary

a. Aluminum inks/pastes are formulated without using a traditional glass frit. A silicon ladder-like polymer, polyphenylsilsesquioxane (“PPSQ”), may be used to formulate Al inks/pastes. The Al ink/paste may comprise micro-sized Al powders, Al nanoparticles (e.g., nanopowders), PPSQ, 2-butoxyethyl acetate, ethyl cellulose, and terpineo 1.

b. Both inks and pastes can be formulated.

c. Sheet resistances down to 3 milliohms/square can be achieved from a PPSQ-based Al ink/paste with a thickness of less than 20 micrometers, as compared with approximately 25 micrometers for most commercial glass frit-based Al inks. This decreases the wafer bow problem for thin solar cells.

d. Resistivities down to 5 micro-ohm-cm are achieved from the PPSQ-based Al inks/pastes.

e. Both micro-sized Al powders and Al nanoparticles (e.g., 100 rim to 500 rim) may be used to formulate Al inks/pastes. No formation of Al beads is observed after sintering with mixtures of various sizes of Al powders including Al nanoparticles.

f. Rapid vacuum sintering in a furnace for about two minutes may be used to sinter an Al ink/paste to achieve lower resistance of Al coatings than can be achieved with sintering in air.

g. An Al ink/paste on silicon may be sintered by microwave radiation to achieve a good conductor.

### Aluminum Ink/Paste for Inkjet Printing

Aluminum ink/paste for inkjet printing may be formulated with aluminum nanoparticles, vehicle, dispersants, binder materials, and functional additives. The sizes of aluminum nanoparticles may be below 500 nm, preferably below 300 nm. The vehicle may include one solvent or a mixture of solvents containing one or more oxygenated organic functional groups. The oxygenated organic compounds refer to medium chain length aliphatic ether acetate, ether alcohols, diols and triols, cellosolves, carbitol, or aromatic ether alcohols, etc. The acetate may be chosen from the list of 2-butoxyethyl acetate, Propylene glycol monomethyl ether acetate, Diethylene glycol monoethyl ether acetate, 2-Ethoxyethyl acetate, Ethylene Glycol Diacetate, etc. The alcohol may be chosen from a list of benzyl alcohol, 2-octanol, isobutanol, and the like. The chosen compounds have boiling points ranging from 100° C. to 250° C.

The weight percentage of dispersants may vary from about 0.5% to 10%. The dispersant may be chosen from organic compounds containing ionic functional groups, such as Disperbyk 180 and Disperbyk 111. Non-ionic dispersant may also be chosen from a list of Triton X-100, Triton X-15, Triton X-45, Triton QS-15, liner alkyl ether (Cola Cap MA259, Cola Cap MA1610), quaternized alkyl imidazoline (Cola Solv IES and Cola Solv TES), and polyvinylpyrrolidone (PVP). The loading concentration of copper nanoparticles may be from about 10% to up to 60%.

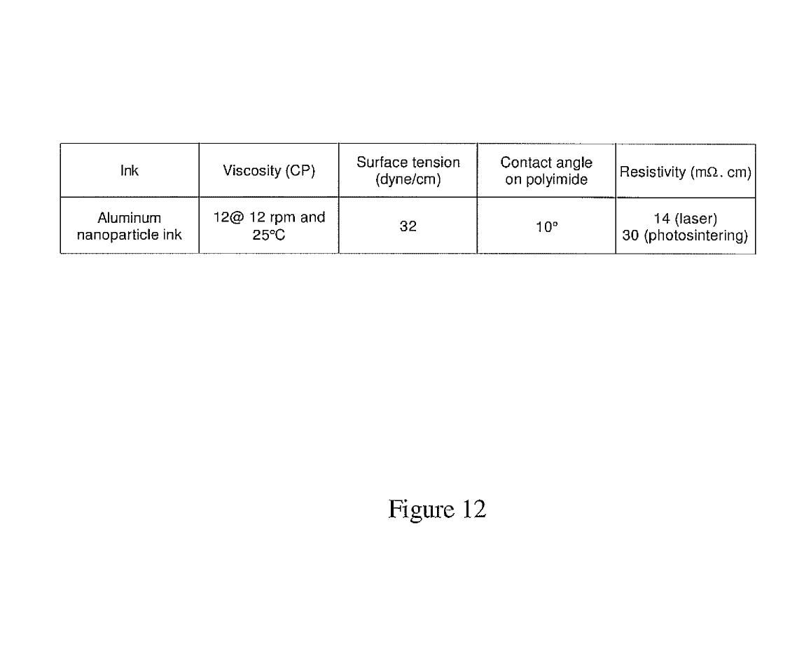

The formulated ink/paste may be mixed by sonication and then ball-milled to improve the dispersion. The formulated aluminum inks may be passed through a filter with a pore size of 1 micrometer. An example of aluminum ink/paste for inkjet printing may be formulated with 2-butoxyethyl acetate, benzyl alcohol, Disperbyk 111, and aluminum nanoparticles with a size below 100 nm. The table in FIG. 12 shows ink/paste properties of examples of the aluminum ink.

As described herein, the ink/paste may be inkjettable with a Dimatix inkjet printer on polymer substrates, such as polyimide. Aluminum ink/paste may be sintered by a laser and photosintering system, which utilizes a light pulse. Laser sintering provides a lower resistivity than photosintering with 1.4×10⁻² Ω·cm attainable. The aluminum ink/paste can also be sintered by other sintering techniques to achieve much lower resistivities, including rapid thermal sintering, belt oven sintering, microwave sintering, etc.

### Aluminum Ink/Paste for Spray Printing

Aluminum ink/paste for spray printing may be formulated with a mixture of micro- and nano-sized aluminum powders. The aluminum ink/paste may contain solvents, dispersants, aluminum powders, and additives.

Silicon-based inorganic polymer material, such as poly(hydromethylsiloxane) (“PHMS”), silicon-ladder polyphenylsilsesquioxane (“PPSQ”) polymer, etc. may be used as a binder material. The inorganic polymer may be dissolved in the ink/paste solvents. Carbon groups in the polymer are removed as the temperature increases leaving a three-dimensional amorphous random network comprising Si—O bonds. The random Si—O networks convert to silicon oxide at temperatures over 650° C. The coefficient of thermal expansion of silicon oxide is close to silicon wafer, and therefore the internal stress between the sintered aluminum and silicon is reduced after sintering at a high temperature. Moreover, the formation of aluminum-silicon alloy at the interface between silicon and sintered aluminum also produces a strong bonding strength film.

An example of aluminum ink/paste for spray printing is formulated with 2-butoxyethyl acetate, benzyl alcohol, Disperbyk 111, PPSQ, and aluminum powders. The aluminum powders may be a mixture of aluminum nanoparticles and micro-size aluminum powders. The size of aluminum nanoparticles may be chosen from about 30 nm to up to about 500 nm. The sizes of micro-sized aluminum powders may be chosen from about 1 micrometer to about 20 micrometers. The viscosity of inks may be modified from about 20 cP to about 2000 cP, depending on which type of deposition techniques is used.

Another example of aluminum ink/paste containing oxide nanoparticles for spray printing may be formulated with 2-butoxyethyl acetate, benzyl alcohol, Disperbyk 111, PPSQ, aluminum powders, and zinc oxide nanoparticles. The aluminum powders may be a mixture of aluminum nanoparticles and micro-size aluminum powders. The sizes of aluminum nanoparticles may be chosen from about 30 nm to up to about 500 nm. The size of micro-sized aluminum powders may be chosen from about 1 micrometer to about 20 micrometers.

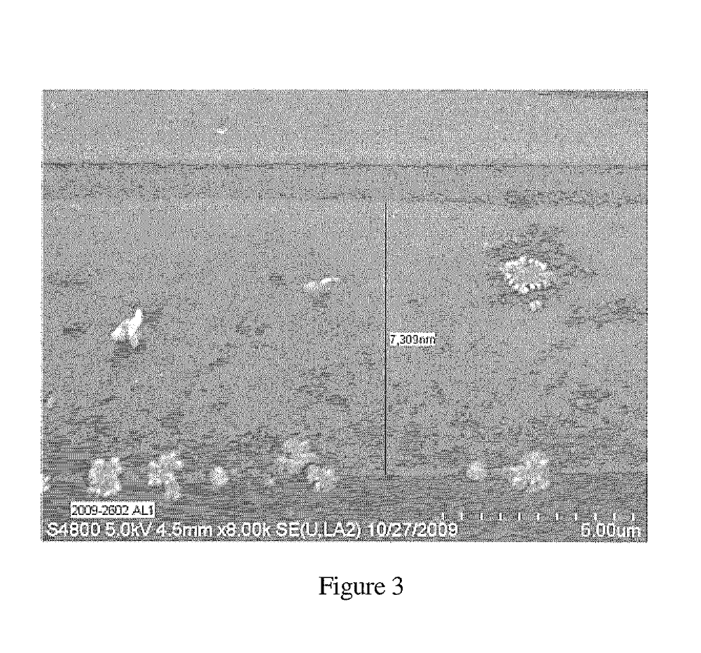

The aluminum ink/paste may be printed by an air brush gun on a P-type silicon wafer. The aluminum coated silicon wafer may be sintered in a thermal tube furnace at about 800° C. in vacuum or in air. A sheet resistance of less than 10 mΩ/cm and a perfect ohmic contact with the silicon is obtained. A BSF layer is formed after thermal sintering, as illustrated in FIG. 3. The BSF layer, which prevents recombination of minority carriers near the interface of the solar cell, is critical to achieve high conversion efficiency for silicon solar cells. Belt furnace and rapid thermal processing systems may also be used to sinter the aluminum inks.

Another example of an aluminum ink/paste for spray printing and a perfect ohmic contact with the silicon may be formulated by using volatile solvents such as 2-propanol, ethanol, acetone, etc. The ink/paste may also include PPSQ, dispersants, and other additives. The volatile solvent helps to prepare more uniform thickness and avoid migration of aluminum during spray.

The formulated ink/paste may be mixed by sonication and then ball-milled to improve the dispersion. The aluminum ink/paste may be sprayed by spray printing techniques, such as air brush spray, compressed air spray gun, atomizing spray gun, etc.

### Aluminum Ink/Paste for Aerosol Jet Printing

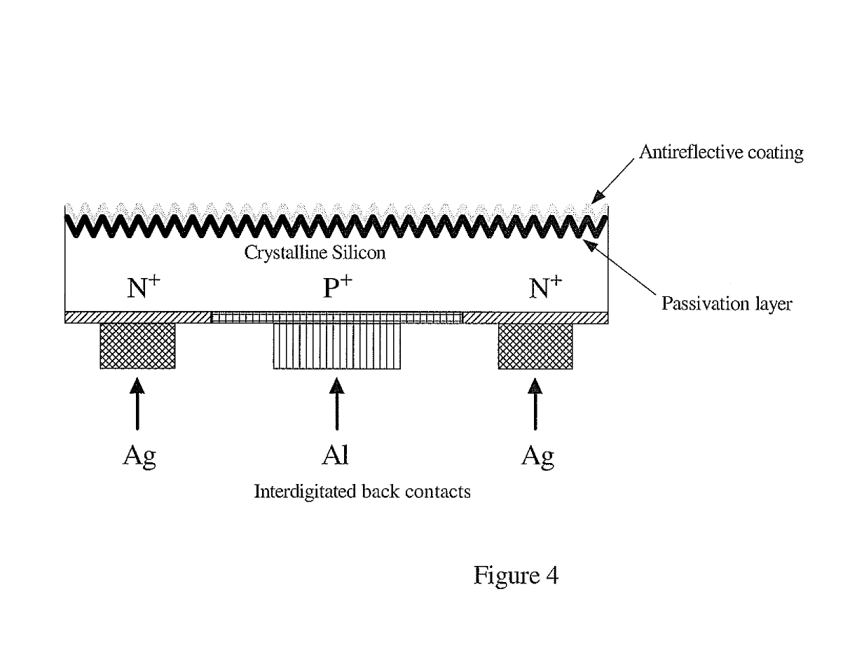

Referring to FIG. 4, rear junction, interdigitated back contact (“IBC”) solar cells have several advantages over front junction solar cells with contacts on either side. Moving all the contacts to the back of the cell eliminates contact shading, leading to a high short-circuit current (“JSC”). With all the contacts on the back of the cell, series resistance losses are reduced as the trade-off between series resistance and reflectance is avoided and contacts can be made far larger. Having all the contacts on the one side simplifies cell stringing during module fabrication and improves the packing factor. The reduced stress on the wafers during interconnection improves yields, especially for large thin wafers. The IBCs are currently fabricated by vacuum deposition and patterned by lithographic processes, which are costly, and it is very difficult to cut manufacturing costs. Current commercially available printing techniques, such as screen printing, are not able to print narrow electrodes for IBCs.

Aerosol jet printing dispenses a collimated beam that allows the resolution to be maintained over a wide range of stand-off distances, and moreover enables larger standoff distances than are possible with inkjet printing. Whereas inkjet printing requires fluids having viscosities less than 20 cP, aerosol jet printing can be used with relatively high viscosity fluids (up to ˜5000 cP) to create aerosol droplets that are 1.5 μm in size. The aerosol jet printing technology can be scaled up by employing multi-nozzles for high volume solar cell manufacturing. Thus, aerosol jet printing techniques can print narrow electrodes for interdigitated back contact solar cells, as shown in. FIG. 4. The silver electrodes can also be printed by an aerosol jet printing technique by using properly formulated silver inks.

Aluminum inks need to be properly formulated for aerosol jet printing. Aluminum ink for aerosol jet printing may be formulated with both micro-sized aluminum powders and nano-sized powders. The aluminum ink may also include proper solvents, dispersants, aluminum powders, and other additives.

An example of aluminum ink for spray printing is formulated with 2-butoxyethyl acetate, benzyl alcohol, Disperbyk 111, PPSQ, and aluminum powders. The aluminum powders may be a mixture of aluminum nanoparticles and micro-size aluminum powders. The sizes of aluminum nanoparticles may be chosen from about 30 nm to up to 500 nm. The sizes of micro-sized aluminum powders may be chosen from about 1 micrometer to 20 micrometers. The viscosity of inks may be modified from about 20 cP to 2000 cP.

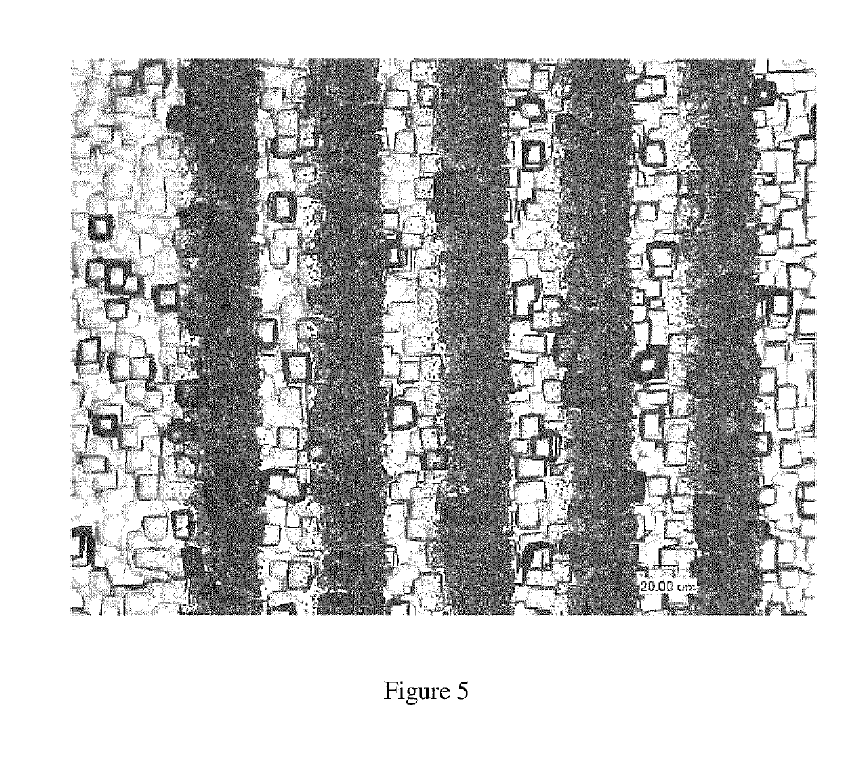

An aerosol jet printer may be used to print fine lines with the formulated aluminum ink. FIG. 5 shows the line width of printed aluminum electrodes on silicon wafer. The aluminum coated silicon wafer may be sintered in a thermal tube furnace at about 800° C. in vacuum or in air. Resistivity of about 10⁻⁵ Ω-cm is obtained. Belt furnace and rapid thermal processing system may also be used to sinter the aluminum inks.

### Molybdenum Inks/Pastes

Molybdenum inks/pastes have been formulated with combinations of alcohols, amines, alkanes (C₆ to C₁₀ chain lengths), long chain alcohols, ether-esters, aromatics, block copolymers, functionalized silanes, and electrostatically stabilized aqueous systems. Nanosized Mo particles have been used in the formulations.

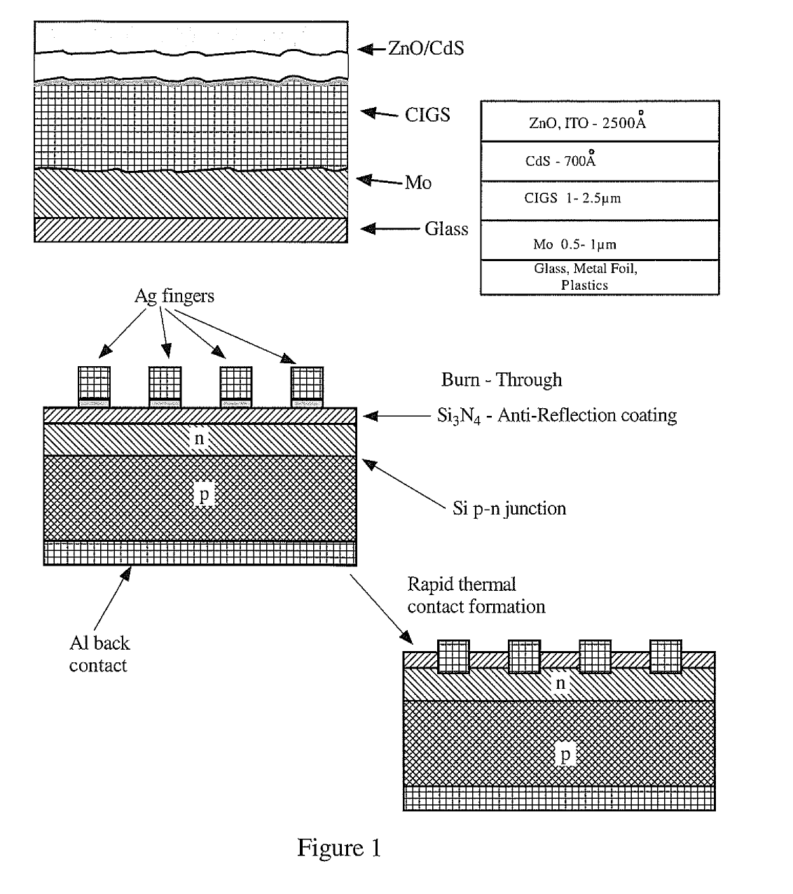

Thin Mo films are used as an adhesive interlayer between a substrate (e.g., glass) and CIGS (copper indium gallium diselenide) photovoltaic films (see FIG. 1). Molybdenum is used for its unique combination of electrical conductivity and adhesive properties with the CIGS and substrate materials. Until this invention, the state of the art technologies for producing these Mo films were ultra-high vacuum techniques, e.g., sputter coating. These techniques are expensive and time consuming, thus not conducive to large scale manufacturing. Alternatively, electroconductive inks/pastes of Mo microparticles could be used to produce the requisite films, however these inks/pastes require very high (˜1600° C.) sintering temperature in order to produce a conductor (see U.S. Pat. Nos. 4,576,735 and 4,381,198, which are hereby incorporated by reference herein). This high temperature cannot be tolerated by other components of CIGS solar cells.

In embodiments of the present invention, a Mo nanoparticle-based ink/paste, or alternatively an ink/paste with a mixture of Mo and Cu nanoparticles, are described that are printed and subsequently dried, then sintered by exposure to high intensity light at room temperature and pressure into a thin conductive film.

### Molybdenum Ink/Paste Formulation

The Mo ink/paste may be formulated with Mo powder (e.g., 2 g of 85 nm Mo nanoparticles), isopropanol (e.g., 1.7 g), and hexylamine (e.g., 0.3 g). The ink/paste may be mixed in a glass jar and agitated in an ultrasonic bath for 10 minutes.

Alternately, for a more stable ink/paste dispersion, the ink may be formulated with Mo powder (e.g., 2 g of 85 nm Mo nanoparticles), hexane (e.g., 1.2 g), and octanol (e.g., 0.1 g). The ink/paste may be mixed in a glass jar and agitated in an ultrasonic bath for 10 minutes.

### Procedure for Making Molybdenum Film on Glass from Molybdenum Ink/Paste

Referring to FIG. 1, a film of Mo ink/paste is produced by draw-down coating onto a glass substrate. The vehicle and dispersant are then removed from the film by thermal drying (e.g., in a 100° C. oven over one hour). The dry film is then exposed to a high intensity visible light for sub-millisecond durations, thus producing the conductive film. This step is referred to as sintering. Before sintering, the dry film has a volume resistivity greater than 2×10⁸ ohm-cm. After sintering, the film sheet resistance is reduced greater than 10 orders of magnitude. Molybdenum films with resistivities as low as 7×10⁻⁴ ohm-cm have been created by this method. After drying and sintering, the final electrode is comprised of almost entirely molybdenum with only small amounts of organic residue remaining. The CIGS layer is then deposited over the molybdenum film.

### Molybdenum and Copper Mixture Ink/Paste Formulation

Mo (e.g., 0.6 g, 85 nm Mo nanoparticles) and Cu (e.g., 0.15 g 50 nm Cu nanoparticles) nanoparticle powders are mixed with isopropanol (e.g., 0.7 g), and octylamine (e.g., 0.2 g). The ink/paste is mixed in a glass jar and agitated in an ultrasonic bath for 10 minutes.

### Procedure for Making Mo Film on Glass from Mo and Cu Ink/Paste

Also referring to FIG. 1, a film of the mixed-metal ink/paste is produced by draw-down coating onto a glass substrate. The vehicle and dispersant are then removed from the film by thermal drying (e.g., in a 100° C. oven over one hour). The dry film is then exposed to a high intensity visible light for sub-millisecond durations, thus producing the conductive film. This step is referred to as sintering. Before sintering, the dry film has a volume resistivity greater than 2×10⁸ ohm-cm. After sintering, the film sheet resistance is reduced greater than 10 orders of magnitude. Mixed Mo and Cu films with resistivities as low as 2.5×10⁻⁴ ohm-cm have been created by this method. After drying and sintering, the final electrode is comprised of almost entirely molybdenum and copper metal with only small amounts of organic residue remaining. The CIGS layer is then deposited over the molybdenum and copper film.

### Summary

a. Inks composed of a vehicle, dispersant, and Mo nanoparticles have been formulated such that upon coating and sintering a conductive Mo film is produced. These films can be used as conductive adhesive interlayers between a CMS photovoltaic material and a support layer, e.g., glass. The resistivity of Mo films produced in this way can be as low as 7×10⁻⁴ ohm-cm.

b. As a way to reduce film resistivity inks with mixtures of nanoparticles comprised of different metals are made into conductive films. Mixtures of Mo and Cu have a threefold improvement compared with Mo alone.

### Aluminum Ink/Paste with Good Suspension

Formulation 1:

This formulation is for non-contact printing techniques, such as aerosol jet printing and spray printing. The aluminum ink/paste (whether it is formulated as an ink or paste may be dependent upon the requirements of the printing apparatus) may be formulated with aluminum powders, solvents, PPSQ solution, binder materials, dispersant, anti-settlement agent, and other functional additives. The sizes of the aluminum powders may be from about 0.2 μm to about 3 μm, or about 0.2 μm to about 2 μm.

The solvents may include one solvent or a mixture of solvents containing one or more oxygenated organic functional groups, one alcohol, ether, etc. The oxygenated organic compounds refer to medium chain length aliphatic ether acetate, ether alcohols, dials and triols, cellosolves, carbitola, or aromatic ether alcohols, etc. The acetate may be chosen from the list of 2-butoxyethyl acetate, Propylene glycol monomethyl ether acetate, Diethylene glycol monoethyl ether acetate, 2-Ethoxyethyl acetate, Ethylene Glycol Diacetate, etc. The alcohol may be chosen from a list of benzyl alcohol, 2-octonal, isobutonal, terpineol, and the like. The chosen compounds have boiling points ranging from 100° C. to 260° C. An anti-settlement agent may be chosen from a list of Disperbyk 410 or Disperbyk 420. The anti-settlement agent is a thixotropic agent to form a high viscosity solution or a gelling material during storage, which prevents the aluminum powders from settling in the solution. The viscosity of the aluminum ink/paste dramatically decreases when it is agitated so that it becomes an ink that may be printed by either spray printing or aerosol jet printing.

The weight percentage of dispersants may vary from about 0.5% to about 10%. The dispersant may be chosen from organic compounds containing ionic functional groups, such as Disperbyk 110 or Disperbyk 111. A non-ionic dispersant may also be chosen from a list of Triton X-100, Triton X-15, Triton X-45, Triton QS-15, liner alkyl ether (Cola Cap MA259, Cola Cap MA1610), quaternized alkyl imidazoline (Cola Solv IES and Cola Solv TES), and polyvinylpyrrolidone (“PVP”). The loading concentration of aluminum may be from about 10% to up to about 70%.

The formulated ink may be mixed by a high shear mixer or sonication. Ball-milling may be also used to further improve the dispersion. An example of aluminum ink for aerosol jet printing may be formulated with diethylene glycol butal ether, benzyl alcohol, Disperbyk 110, Disperbyk 410, PPSQ solution, and aluminum powders with sizes less than ˜3 μm.

The aluminum ink may be printed by an aerosol jet printer onto a silicon wafer. A TLM (transmission line method) pattern may be printed to obtain contact resistivity. Then, the printed aluminum ink may be dried at 100° C., or 200° C. to 250° C. in air, to remove the solvents in the printed aluminum ink. The dried aluminum ink may be sintered either in air or vacuum from ˜530° C. to ˜940° C. to form a good conductor. Table 1 shows the electrical data after the aluminum ink is sintered.

TABLE 1

| | | | Sheet | | |
|---|---|---|---|---|---|
| | Al | | resistance | Contact | |
| Ink | Powder | Viscosity | (mΩ/square) | resistivity | Thickness |
| Formula- | <3 μm | >90 cP | <60 | 10⁻²-10⁻³ | 3-15 μm |
| tion 1 | | | | Ω · cm² | |

Low contact resistance is desired for aluminum ink on silicon solar cells. With printed aluminum ink, contact resistivity on both N-type and P-type silicon wafers ranging from about 10⁻²-10⁻³ Ω·cm² have been obtained. With a surface treatment to remove surface aluminum oxide on sintered aluminum ink, copper plating on sintered aluminum ink has been demonstrated.

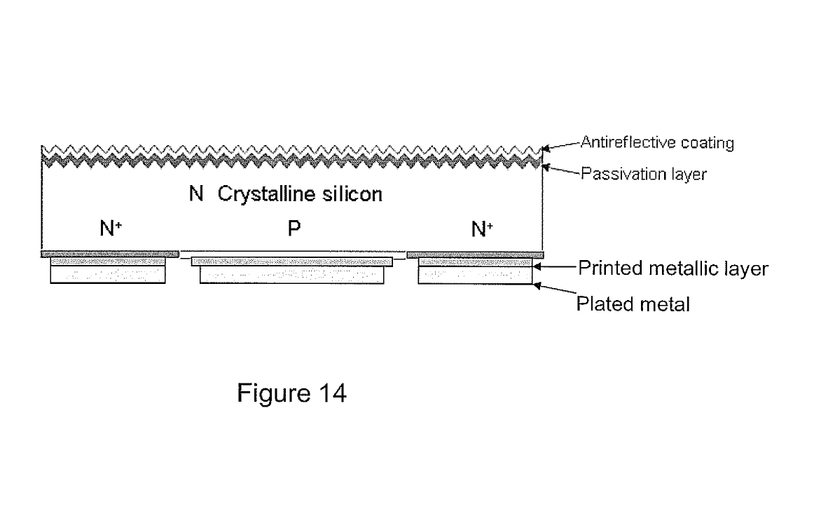

Referring to FIG. 14, the aluminum ink may be printed on all back contact electrodes of an IBC silicon solar cell (e.g., as a seed layer for copper plating). As disclosed herein, during sintering, the aluminum ink forms low ohmic contacts between the silicon and printed metallic layers on both the N-type zones and P-type zones. Such printing processes eliminate costly and vacuum deposition and photolithographic processes, providing a cost-effective metallization process for all back contact silicon solar cells. Damaging of thin silicon wafers is also mitigated.

The sintered aluminum film on the IBC electrodes, can act as a seed layer to thicken the electrodes by plating conductive metal onto the printed metallic layers, which can lower electrode resistance to reduce the series resistance of the solar cell, which results in a higher cell conversion efficiency. The plating process may be performed by electroless plating or electrical plating. The plated metals may be copper, silver, nickel, tin, etc. The plated metals may be only one of copper, silver, nickel, tin, etc., or a combination of two or more of such metals. Other types of pastes, such as copper paste, silver paste, nickel paste, etc., may also be used to print on aluminum paste electrode to reduce overall resistance.

Formulation 2:

Based on Formulation 1, other powders such as tin, zinc, bismuth, titanium, gallium, boron, silicon, etc., may be added into the aluminum inks. The loading concentration of the powders may range from about 0.5% to about 5%. The addition of such powders may be one of them or a combination of them. The sizes of powders may be nanoparticles or micro-sized particles below 3 micrometers.

Formulation 3:

Based on Formulation 1, other inorganic metal salts may also be added to form a glass-frit like material to produce adhesion on silicon and matching coefficient of thermal expansion. The organic metal salts may be dissolved in solvents and may be decomposed into metal or form oxides during sintering in air. The solvents and additives in Formulation 1 may be used to formulate Al-silicon based inks.

Formulation 4

Another approach to obtain adhesion and matching coefficient of thermal expansion to silicon is to have in-situ synthesis of glass-like material during sintering. One of the examples is to combine a PPSQ solution, B₂O₃ solution, and low-cost ZnO nanoparticles together to form a good suspension. The B₂O₃ solution may be dissolved in an alcohol-based solvent, such as ethanol, benzyl alcohol, etc. During sintering, PPSQ converts into a Si—O type of structure, which can react with B₂O₃ and ZnO to form a glass-like material, therefore forming adhesion to silicon and matching CTE to silicon by adjusting the ratio of PPSQ, B₂O₃, and ZnO. The solvents and additives in Formulation 1 may be used to formulate Al-silicon based inks.

Formulation 5

To avoid aluminum spiking or pitting on silicon P-N junctions of solar cells, silicon may be added into aluminum inks, or an aluminum silicon alloy may be used to formulate aluminum inks instead of using pure aluminum powders. Silicon nanoparticles with a sizes less than 100 nm may be added into the aluminum inks. The concentration of silicon may be from about 5% to about 50%. Aluminum silicon alloy powders (e.g., silicon concentration from about 1%-20%) may be also used to formulate an Al ink to prevent pitting on the silicon when fired. The solvents and additives in Formulation 1 may be used to formulate Al-silicon based inks. The silicon content aluminum ink may also be formulated as a paste for screen printing, stencil printing. The silicon content aluminum pastes may also be used to reduce aluminum spiking on both P-doped silicon and N-doped silicon to reduce surface carrier recombination and avoid damage to the P-N junctions of the silicon solar cell.

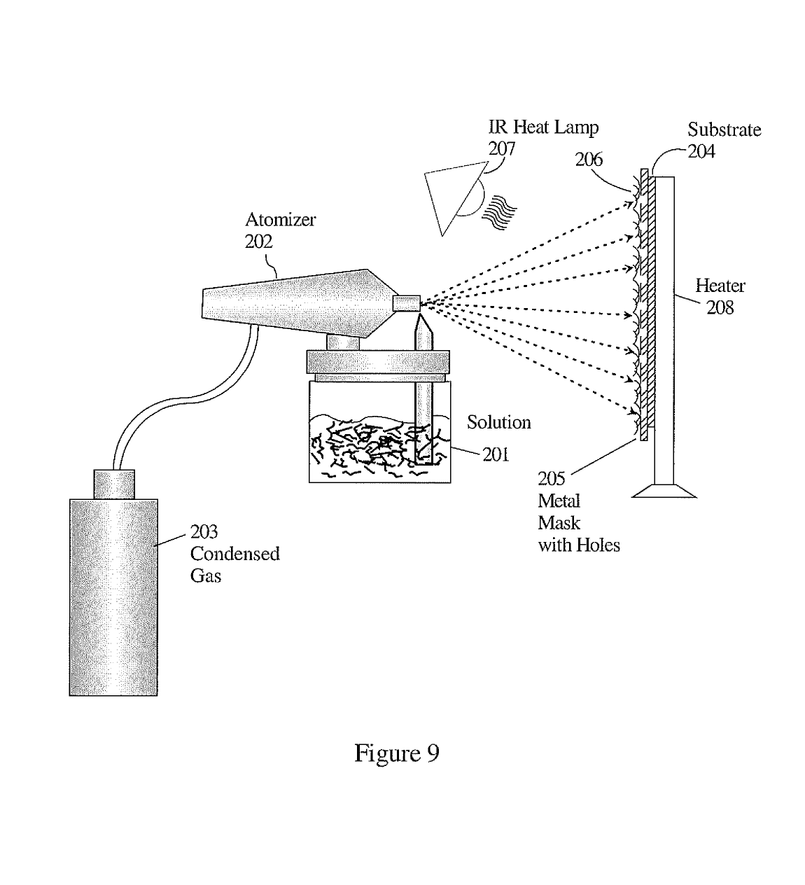

Referring to FIG. 9, an aerosol process is illustrated for applying embodiments of the inks described herein. Condensed gas 203 can charges an aerosol atomizer 202 to create the spray from the ink/paste solution 201. The ink/paste mixture 206 may be sprayed on selected areas by using a shadow mask 205. In order to prevent the solution 206 from flowing to unexpected areas, the substrate 204 may be heated up to 50° C.-100° C. both on the front side and back side during the spray process. The substrate 204 may be sprayed back and forth or up and down several times until the mixture 206 covers the entire surface uniformly. Then they may be dried in air naturally or using a heat lamp 207. Heating of the substrate may also be used.

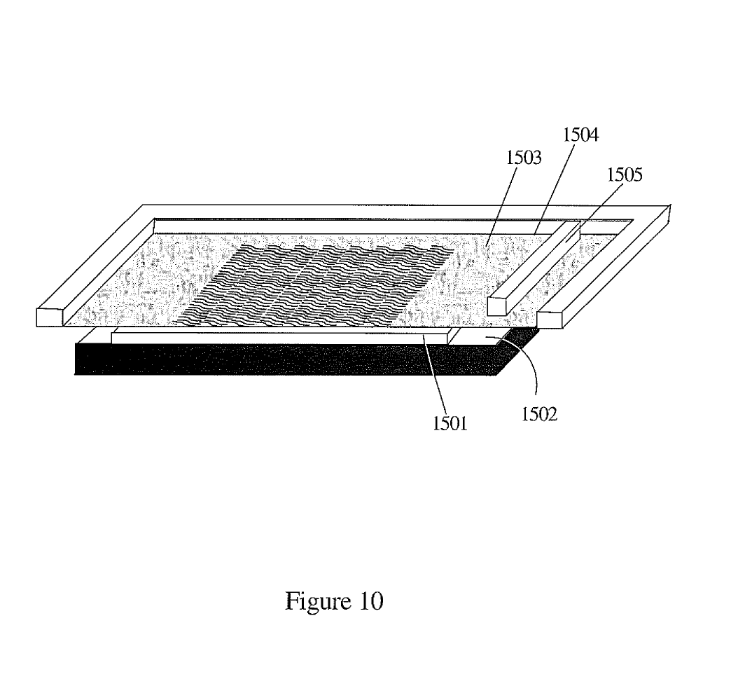

FIG. 10 illustrates a screen printing method by which ink/paste mixtures may be deposited onto a substrate according to embodiments of the present invention. A substrate 1501 is placed on a substrate stage/chuck 1502 and brought in contact with an image screen stencil 1503. An ink/paste mixture 1504 (as may be produced using methods described herein) is then “wiped” across the image screen stencil 1503 with a squeegee 1505. The mixture 1504 then contacts the substrate 1501 only in the regions directly beneath the openings in the image screen stencil 1503. The substrate stage/chuck 1502 is then lowered to reveal the patterned material on the substrate 1501. The patterned substrate is then removed from the substrate stage/chuck.

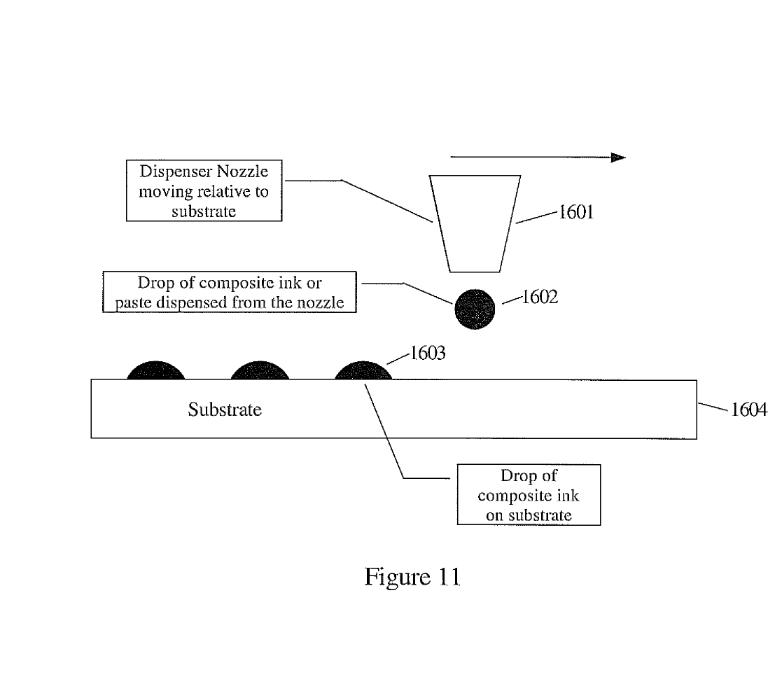

FIG. 11 illustrates an embodiment wherein a dispenser or an inkjet printer may be used to deposit an ink/paste mixture onto a substrate according to embodiments of the present invention. A printing head 1601 is translated over a substrate 1604 in a desired manner. As it is translated over the substrate 1604, the printing head 1601 sprays droplets 1602 comprising the ink/paste mixture. As these droplets 1602 contact the substrate 1604, they form the printed material 1603. In some embodiments, the substrate 1604 is heated so as to effect rapid evaporation of a solvent within said droplets. Such a substrate temperature may be about 70° C.-80° C. Heat and/or ultrasonic energy may be applied to the printing head 1601 during dispensing. Further, multiple heads may be used.

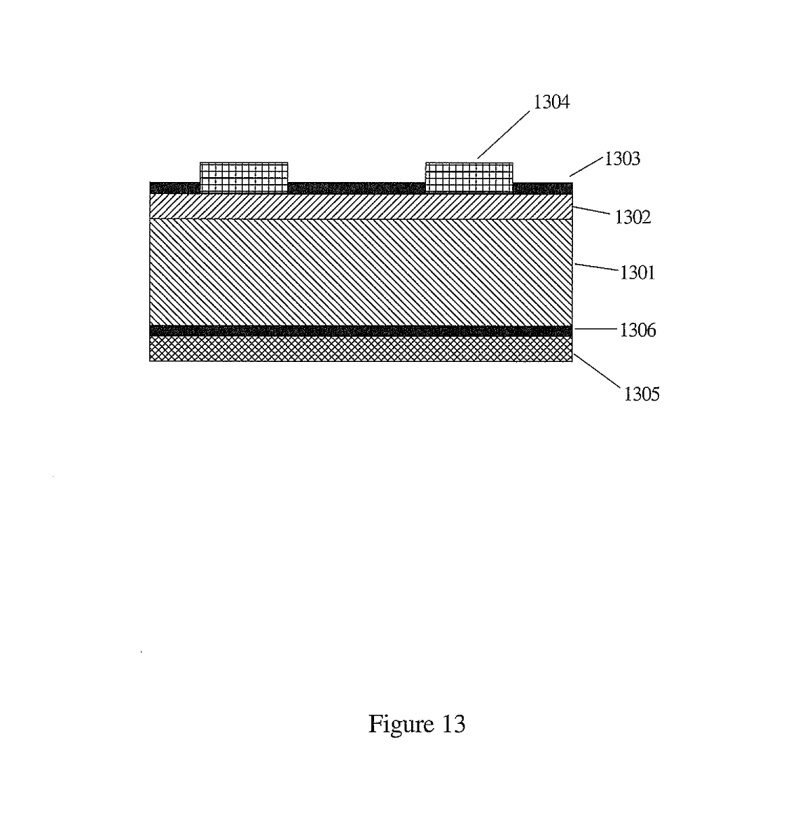

FIG. 13 illustrates a solar cell device produced by using a P-type monocrystalline or polycrystalline silicon substrate 1301 whose thickness may be from about 100 μm to about 300 μm. An N-type silicon emitter layer 1302 as prepared by diffusion is produced after surface treatments. Then an antireflective and passivation layer 1303, typically a silicon nitride layer produced by chemical vapor deposition, is formed on an N-type layer 1302. Front grid electrodes 1304 are then formed on the passivation layer 1303. Front grid electrodes 1304 may be printed by using silver inks. Aluminum ink/paste is printed as the back contact electrode 1305.

The front grid electrodes 1304 and back aluminum contact 1305 may be co-fired or fired separately. After firing, an ohmic contact is formed between the grid electrodes 1304 and N-type layer 1302. Aluminum-silicon alloy and BSF (Back Surface Field) layer 1306 according to embodiments of the present invention is also formed in the interface between the aluminum layer and P-type silicon by diffusion during a firing process.

Unless defined otherwise, all technical and scientific terms used herein have the same meaning as commonly understood to one of ordinary skill in the art to which the presently disclosed subject matter belongs.

Following long-standing patent law convention, the terms “a” and “an” mean “one or more” when used in this application, including the claims.

Unless otherwise indicated, all numbers expressing quantities of ingredients, reaction conditions, and so forth used in the specification and claims are to be understood as being modified in all instances by the term “about.” Accordingly, unless indicated to the contrary, the numerical parameters set forth in this specification and attached claims are approximations that can vary depending upon the desired properties sought to be obtained by the presently disclosed subject matter.

As used herein, the terms “about,” “approximately,” and “˜” when referring to a value or to an amount of mass, weight, time, volume, concentration or percentage is meant to encompass variations of in some embodiments ±20%, in some embodiments ±10%, in some embodiments ±5%, in some embodiments ±1%, in some embodiments ±0.5%, and in some embodiments ±0.1% from the specified amount, as such variations are appropriate to perform the disclosed method.

As used herein, the term “and/or” when used in the context of a listing of entities, refers to the entities being present singly or in combination. Thus, for example, the phrase “A, B, C, and/or D” includes A, B, C, and D individually, but also includes any and all combinations and subcombinations of A, B, C, and D. The term “comprising,” which is synonymous with “including,” “containing,” or “characterized by,” is inclusive or open-ended and does not exclude additional, unrecited elements or method steps. “Comprising” is a term of art used in claim language which means that the named elements are present, but other elements can be added and still form a construct or method within the scope of the claim.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a defacto equivalent of any other member of the same list solely based on their presentation in a common group without indications to the contrary.

Concentrations, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a numerical range of approximately 1 to approximately 4.5 should be interpreted to include not only the explicitly recited limits of 1 to approximately 4.5, but also to include individual numerals such as 2, 3, 4, and sub-ranges such as 1 to 3, 2 to 4, etc. The same principle applies to ranges reciting only one numerical value, such as “less than approximately 4.5,” which should be interpreted to include all of the above-recited values and ranges. Further, such an interpretation should apply regardless of the breadth of the range or the characteristic being described.

What is claimed is:

1. A method for making a silicon solar cell comprising:
printing an aluminum ink composition on the silicon solar cell to form one or more contact electrodes; and
sintering the aluminum ink composition forming a first one of the one or more contact electrodes to produce an ohmic contact on the silicon solar cell.

2. The method for making the silicon solar cell as recited in claim 1, wherein the aluminum ink composition further comprises aluminum powders, a vehicle, an inorganic polymer, and a dispersant.

3. The method for making the silicon solar cell as recited in claim 2, wherein the aluminum powders comprise micro-sized aluminum powders having sizes from about 1 μm to about 20 μm and aluminum nanoparticles having sizes from about 30 nm to about 500 nm.

4. The method for making the silicon solar cell as recited in claim 2, wherein the aluminum powders are aluminum silicon alloy powders that comprise silicon with a concentration from about 1% to about 20%.

5. The method for making the silicon solar cell as recited in claim 2, wherein the inorganic polymer is a silicon-containing inorganic polymer, wherein during the sintering of the aluminum ink composition, silicon in the silicon-containing inorganic polymer decreases a thermal expansion mismatch between the sintered aluminum powders and silicon in the silicon solar cell to thereby decrease a resistance of the ohmic contact.

6. The method for making the silicon solar cell as recited in claim 2, wherein the inorganic polymer is a silicon-containing inorganic polymer, wherein during the sintering of the aluminum ink composition, an amorphous random network comprising Si—O bonds is produced in the silicon-containing inorganic polymer that converts to silicon oxide.

7. The method for making the silicon solar cell as recited in claim 2, wherein the silicon-containing inorganic polymer is further configured to form an aluminum-silicon alloy at an interface between the silicon solar cell and the fired aluminum powders.

8. The method for making the silicon solar cell as recited in claim 2, wherein the inorganic polymer is polyphenylsilsesquioxane.

9. The method for making the silicon solar cell as recited in claim 2, wherein the inorganic polymer is poly(hydromethylsiloxane).

10. The method for making the silicon solar cell as recited in claim 1, wherein the silicon solar cell is a rear junction, interdigitated back contact solar cell.

11. The method for making the silicon solar cell as recited in claim 10, wherein the printing of the aluminum ink composition on the silicon solar cell to form one or more contact electrodes comprises printing the aluminum ink composition on N and P zones of the rear junction, interdigitated back contact solar cell to form back contact electrodes.

12. The method for making the silicon solar cell as recited in claim 11, wherein the sintered aluminum ink composition includes a plating seed layer for metal plating.

13. The method for making the silicon solar cell as recited in claim 12, further comprising plating a metal layer onto the sintered one or more contact electrodes.

14. The method for making the silicon solar cell as recited in claim 1, wherein the printing is performed with an apparatus selected from the group consisting of an inkjet printer, spray printer, and aerosol jet printer.

15. The method for making the silicon solar cell as recited in claim 1, wherein the printing is performed with an apparatus selected from the group consisting of a screen printer and a stencil printer.

16. The method for making the silicon solar cell as recited in claim 2, wherein the aluminum ink composition further comprises a thixotropic agent to increase a viscosity of the aluminum ink composition, which prevents the aluminum powders from settling in the aluminum ink composition during storage of the aluminum ink composition.

17. The method for making the silicon solar cell as recited in claim 1, wherein the aluminum ink composition does not include glass frit.

18. A method for making a rear junction, interdigitated back contact solar cell comprising:
forming an N-type silicon layer on a P-type silicon semiconductor substrate;
printing an aluminum ink composition on a back of the silicon semiconductor substrate to form one or more back contact electrodes, wherein the aluminum ink composition further comprises aluminum powders and a silicon-containing inorganic polymer; and
sintering the aluminum ink composition forming a first one of the one or more back contact electrodes to produce an ohmic contact between the N-type silicon layer and a first one of the one or more back contact electrodes of the rear junction, interdigitated back contact solar cell.

19. The method for making the rear junction, interdigitated back contact solar cell as recited in claim 18, wherein the sintering of the aluminum ink composition comprises decreasing a thermal expansion mismatch between the sintered aluminum powders and silicon in the silicon semiconductor substrate to thereby decrease a resistance of the ohmic contact.

20. The method for making the rear junction, interdigitated back contact solar cell as recited in claim 18, further comprising sintering the aluminum ink composition forming a second one of the one or more back contact electrodes to produce an ohmic contact between the P-type silicon semiconductor substrate and the second one of the one or more back contact electrodes of the rear junction, interdigitated back contact solar cell.
